(19) United States
(12) Patent Application Publication
(10) Pub. No.: US 2013/0120010 A1
(43) Pub. Date: May 16, 2013

(54) Power Measurement System for Battery Powered Microelectronic Chipsets

(71) Applicants: Clement B. Edgar, III, San Diego, CA (US); Brett L. Christensen, San Diego, CA (US); Christopher A. Barrett, Boulder, CO (US); Lakshmi P. Baskaran, San Diego, CA (US); Christopher F. Einsmann, San Diego, CA (US); Karthik N. Moncombu Ramakrishnan, San Diego, CA (US); Alfonso T. Trujillo, San Diego, CA (US); Alejandro Trujillo, San Diego, CA (US)

(72) Inventors: Clement B. Edgar, III, San Diego, CA (US); Brett L. Christensen, San Diego, CA (US); Christopher A. Barrett, Boulder, CO (US); Lakshmi P. Baskaran, San Diego, CA (US); Christopher F. Einsmann, San Diego, CA (US); Karthik N. Moncombu Ramakrishnan, San Diego, CA (US); Alfonso T. Trujillo, San Diego, CA (US); Alejandro Trujillo, San Diego, CA (US)

(73) Assignee: QUALCOMM Incorporated, San Diego, CA (US)

(21) Appl. No.: 13/476,046

(22) Filed: May 21, 2012

Related U.S. Application Data
(60) Provisional application No. 61/557,943, filed on Nov. 10, 2011.

(51) Int. Cl. G01R 21/06

(52) U.S. Cl. 324/750.01

(57) ABSTRACT

A measurement instrument includes selectable channels for simultaneously measuring current on a power rail/load of a device under test. Multiplexor circuitry can be controlled to select power rails/loads for measurement and to couple unselected power rails to bypass the measurement circuitry. Active loads are provided in the measurement circuitry to compensate for loading by the measurement circuitry. The active loads cause current on a source side of a selected power rail/load to match current measured on a load side of the selected power rail/load during power measurements.

### CROSS REFERENCE TO RELATED APPLICATION

The present application claims the benefit of U.S. Provisional Patent Application No. 61/557,943, entitled Power Measurement System for Battery Powered Microelectronic Chipsets, filed on Nov. 10, 2011.

### TECHNICAL FIELD

The present disclosure generally relates to power measurement systems for microelectronic devices. More specifically, the present disclosure relates to improving accuracy of current and voltage measurements over time for individual loads and rails of multimedia and wireless chipsets.

### BACKGROUND

In order to design chipsets with reduced power consumption, accurate measurements of voltage and current relative to time are required. The amount of power consumed by multimedia and wireless chipsets is determined by both hardware and software. Such chipsets may include complex power grids with 50 or more independent rails and 100 or more loads.

Existing commercial instruments can measure voltage and current very accurately (>0.01%), but they generally provide readings slowly so that the readings represent average levels over time. Measurement ranges for such instruments may be sufficient for many applications but may only be available on a few channels. Some examples of existing commercial measuring devices include precision multi-meters, voltmeters, current meters, power supplies, and electronic loads. Other existing commercial instruments can measure voltage precisely in time, but have relatively low accuracy. Some such instruments provide only a few measurement channels with limited measurement ranges. Examples of this type of instrument include digital sampling oscilloscopes.

Other existing commercial instruments such as data acquisition cards and instruments provide a moderate number of channels with good timing information. However, the measurement range and accuracy of commercially available data acquisition cards is often limited. It is often problematic to perform current measurements using a commercially available data acquisition card or data acquisition instruments. Measurement circuitry in the data acquisition cards may impose a load on a power rail under test that may affect the measured current or the behavior of a device under test. Furthermore, presently used commercial instruments generally do not provide a time correlation between power changes on a particular channel and events that trigger the power changes.

### BRIEF SUMMARY

One aspect of the present disclosure includes a method for measuring power in a device under test. The method includes coupling a measurement system interface circuitry in series with a power rail from a power source to the device under test, receiving an input voltage on a first portion of the power rail from the power source to an input node of the measurement system interface circuitry, and providing an output on a second portion of the power rail from the measurement system interface circuitry to the device under test. The current, power and/or voltage provided to the second portion of the power rail is measured. The amount of current sinked from the first portion of the power rail on the input node is actively controlled to reflect current provided to the device under test on the second portion of the power rail.

In yet another aspect, an apparatus for measuring power in a device under test has means for coupling measurement system interface circuitry in series with a power rail from a power source to the device under test. The apparatus also has means for receiving an input on a first portion of the power rail from the power source to an input node of the measurement system interface circuitry. The apparatus further includes means for providing an output on a second portion of the power rail from the measurement system interface circuitry to the device under test. The apparatus also includes means for measuring a current, power and/or voltage provided to the second portion of the power rail; and means for actively controlling an amount of current sinked from the first portion of the power rail on the input node to reflect current provided to the second portion of the power rail.

Another aspect of the present disclosure includes an apparatus for measuring power in a device under test. The apparatus includes multiplexor circuitry coupled to multiple power rails of the device under test. The multiplexor circuitry is configured to selectively couple a measurement channel in series with a selected power rail. An input node of the measurement channel is coupled to a first source side of the selected power rail. An output node of the measurement channel is coupled to a first load side of the selected power rail. Remote sense circuitry is coupled between the input node and the output node. The remote sense circuitry is configured to actively adjust a first current through the input node to mirror a second current through the output node.

This has outlined, rather broadly, the features and technical advantages of the present disclosure in order that the detailed description that follows may be better understood. Additional features and advantages of the disclosure will be described below. It should be appreciated by those skilled in the art that, this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is schematic block diagram of a measurement instrument configured to measure power on power rails/loads of a device under test according to aspects of the present disclosure.

FIG. 2 is schematic circuit diagram of measurement system interface circuitry configured to measure power on a power rail/load of a device under test according to aspects of the present disclosure.

FIG. 3 is process flow diagram illustrating a method of measuring power in a device under test according to aspects of the present disclosure.

FIG. 4 is a block diagram showing an exemplary wireless communication system in which a configuration of the disclosure may be advantageously employed.

FIG. 5 is a block diagram illustrating a design workstation used for circuit, layout, and logic design of a semiconductor component according to one configuration.

### DETAILED DESCRIPTION

Aspects of the present disclosure provide an instrument to measure power by measuring voltage and current on multiple nominally DC power supply rails used in microelectronic devices and systems. More specifically, aspects of the present disclosure provide an instrument that precisely measures voltage and current relative to each other over time. Aspects of the present disclosure provide time correlation between power changes on a particular channel and events that trigger the power changes. The instrument is capable of accurately measuring power on multiple channels on prototype chipsets and devices such as multimedia radio devices.

According to aspects of the present disclosure, accurate power measurements may be performed over time for individual loads and rails of multimedia and wireless chipsets. These measurements can be used to improve power distribution and reduce power consumption of the chipsets, for example. Accurate power measurements of individual loads and rails can be used to improve and debug hardware and software, for example.

Aspects of the present disclosure include active circuitry configured to compensate for the voltage drop across current measurement shunt resistors and for other power losses within a measurement system. The active circuitry ensures the current load on a power supply side of a power rail/load under test is the same during measurement as it would be if the power rail under test had not been coupled to the power measurement circuitry. Remote sensing is used to compensate for losses in the measurement system.

According to aspects of the present disclosure, power measurements can be performed with greater than 99% accuracy. Current measurements may be performed with current levels from μA levels to several amps and on waveforms at 500 kilo-samples per second (KSPS) or more. In one implementation, accurate power measurements may be performed at up to 1.25 mega-samples per second (MSPS) on one channel or up to 750 KSPS aggregated over several channels.

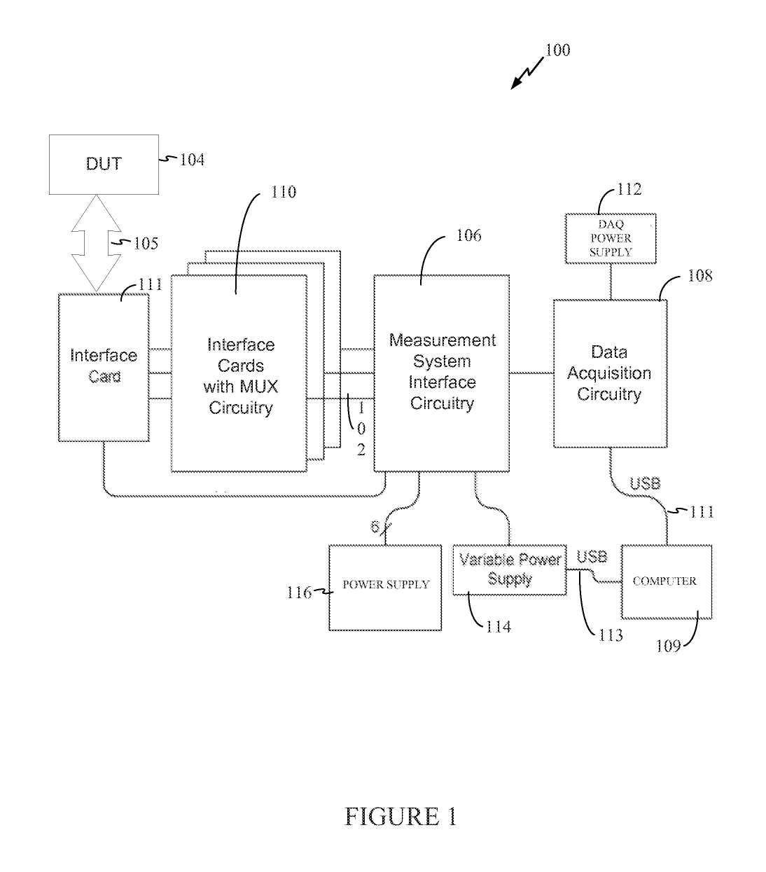

Referring to FIG. 1, an implementation of power measurement circuitry according to aspects of the present disclosure includes a measurement instrument 100 configured to measure voltages and currents on power rails of a device under test (DUT) 104. The measurement instrument 100 includes measurement system interface circuitry 106 coupled between the device under test 104 and data acquisition circuitry 108. The measurement instrument 100 may coupled to a computer 109 via a first universal serial bus (USB) cable 111, for example. A data acquisition (DAQ) power supply 112 is coupled to the data acquisition circuitry 108. A variable power supply 114 and a multi-channel DC power supply 116 are coupled to the measurement system interface circuitry 106. The computer 109 may be coupled to the variable power supply 114 via a second USB cable 113, for example.

In one implementation, the measurement instrument 100 connects to the DUT 104 via a large board-to-board connector 105. However, it should be understood that various other low resistance interconnection means, such as multi-conductor cabling and connector terminals, for example, may be used to provide connections between the measurement instrument 100 and the DUT 104 according to the present disclosure. The DUT 104 may be a platform used to test low power, micro-electronic digital systems with many power supply rails, for example. Particular examples of DUTs that can be subject to measurement according to aspects of the present disclosure include various test platforms and development platforms that are designed and built for the development and test of particular chipsets.

The measurement instrument 100 may include multiple voltage and current measurement channels 102, that can each measure voltage and current on a selected power rail/load of the DUT 104. Interface modules 110, are coupled between the measurement channels 102 and the DUT 104. In one implementation, the interface modules 110, include multiplexer circuitry in which a number of low resistance field effect transistor (FET) switches are configured to select the power rails to be measured from a number of power rails/loads on the DUT 104. Voltage measurements on the selected power rails may be performed substantially simultaneously with the current measurements on the same power rails/loads to provide an accurate power measurement for each selected power rail/load.

According to aspects of the present disclosure, the measurement instrument 100 may be configured and controlled by the computer 109. The computer may be configured to control the multiplexor circuitry for selecting power rails/loads to be measured and may also control the output of the variable power supply 114, for example. Unmeasured power rails are bypassed by shorting input to output using the low resistance FETs in interface modules 110.

The measurement system interface circuitry 106 includes active measurement channels that improve accuracy of current and voltage measurements. The active measurement channels compensate for resistive losses in the measurement system interface circuitry 106. Such resistive losses may result from current measurement through a shunt resistor and from wiring within the measurement system interface circuitry 106, for example. Voltage and current levels on a selected power tail are simultaneously measured on the active channels and resulting measurement signals are output from the measurement system interface circuitry 106 to the data acquisition circuitry 108. Passive channels, which do not compensate for internal losses, may be used in addition to the active channels.

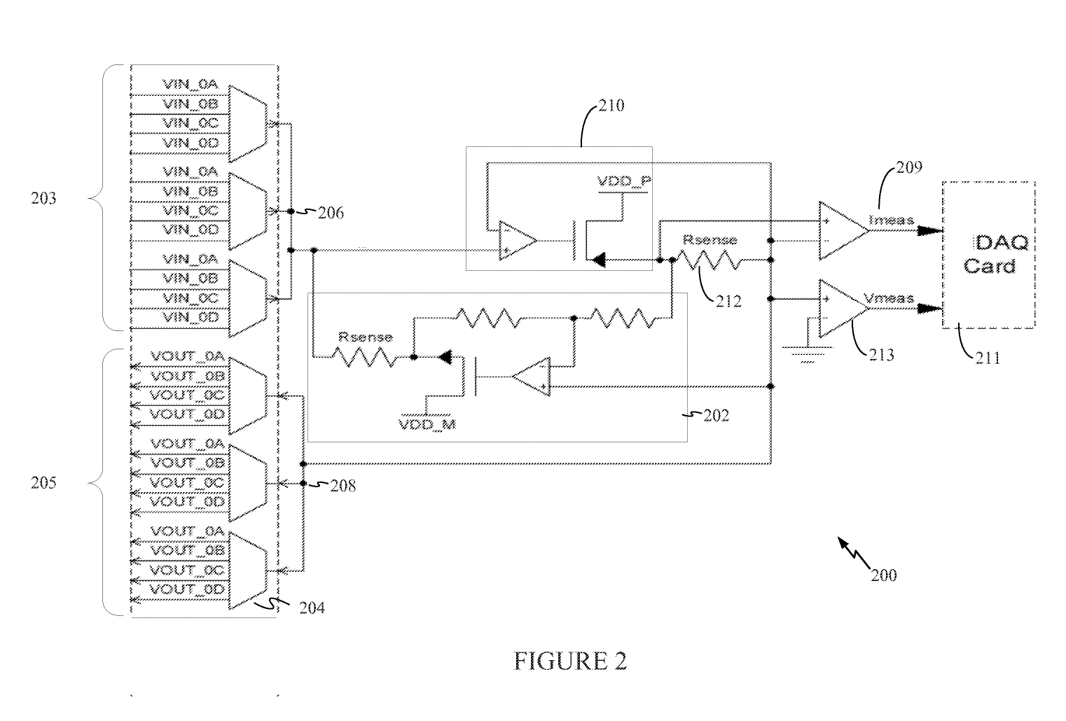

FIG. 2 is a schematic diagram of a measurement channel 200 of a power measurement instrument according to aspects of the present disclosure. Multiplexor circuitry 204 is coupled to power rails of the device under test and configured to selectively couple one of the power rails to the measurement channel. The multiplexor circuitry 204 divides a selected power rail into a source side 203 and a load side 205 and couples the measurement channel in series with the power rail between the source side 203 and the load side 205.

An input node 206 of the measurement channel is coupled to the source side 203 on a first portion of the selected power rail and an output node 208 of the measurement channel is coupled to the load side 205 on a second portion of the selected power rail. The multiplexor circuitry 204 is also configured to short the source side 203 of each unselected power rail to a corresponding load side 205 of the unselected path to bypass the measurement channel.

The input node 206 is coupled to a first active load circuitry 202 and second active load circuitry 210. The first active load circuitry 202 and second active load circuitry 210 control current through a current sense shunt resistor 212 in response to a voltage difference between the input node 206 and the output node 208. A first measurement amplifier 209 is coupled across the current sense shunt resistor 212 and provides a current measurement output signal to data acquisition circuitry 211. A second measurement amplifier 213 is coupled to the output node 208 and to ground to provide a voltage measurement signal to the data acquisition circuitry 211.

The first active load circuitry 202 and second active load circuitry 210 senses current at the output node 208 and provides a current adjustment to the input node 206 based on the output node current level. This configuration effectively mirrors current of the output node 208 onto the input node 206 to compensate for effects of the measurement circuitry on the input node current. Without such compensation, the source side 203 of the selected power rail would not be subject to the load side's current draw.

By reflecting the measured load side current onto the source side 203 of a selected power rail during power measurements according to aspects of the present disclosure, the resulting power measurements accurately represents conditions on the selected power rail. Operational behavior of the device under test is therefore more accurately simulated without distortions on a power rail due to loading effects of the measurement system circuitry.

In one configuration, the power measurement instrument includes means, for coupling measurement system interface circuitry in series with a power rail from a power source to the device under test, means for receiving an input signal on a power rail from the power source to an input node of the measurement system interface circuitry, and means for providing an output signal on a power rail from the measurement system interface circuitry to the device under test. The means for coupling in series with a power rail, means for receiving an input signal and means for providing an output signal may be multiplexor circuitry 204, for example. In this configuration, the power measurement instrument may also include means for measuring current of the output signal, such as sense shunt resistor 212 and/or first measurement amplifier 209, and means for actively controlling current of the input signal to reflect output signal current in response to the measured output signal current, such as first active load circuitry 202, for example.

According to aspects of the present disclosure, the power measurement instrument may also include means, such as multiplexor circuitry 204, for selecting the power rail from a number of power rails in the device under test and means, such as the first active load 210, for comparing a voltage of the input signal to a voltage of the output signal, for example. Aspects of the disclosure also include means, such as first active load circuitry 202, for controlling output current based on a difference between the voltage of the input signal and the voltage of the output signal, and means, such as the first active load 210, for controlling a voltage of the output signal based on a voltage of the input signal.

In one aspect, any or all of the aforementioned means may be included in the measurement channel 200 and configured to perform the recited functions. In another aspect, the aforementioned means may be any module or any apparatus configured to perform the functions recited by the aforementioned means.

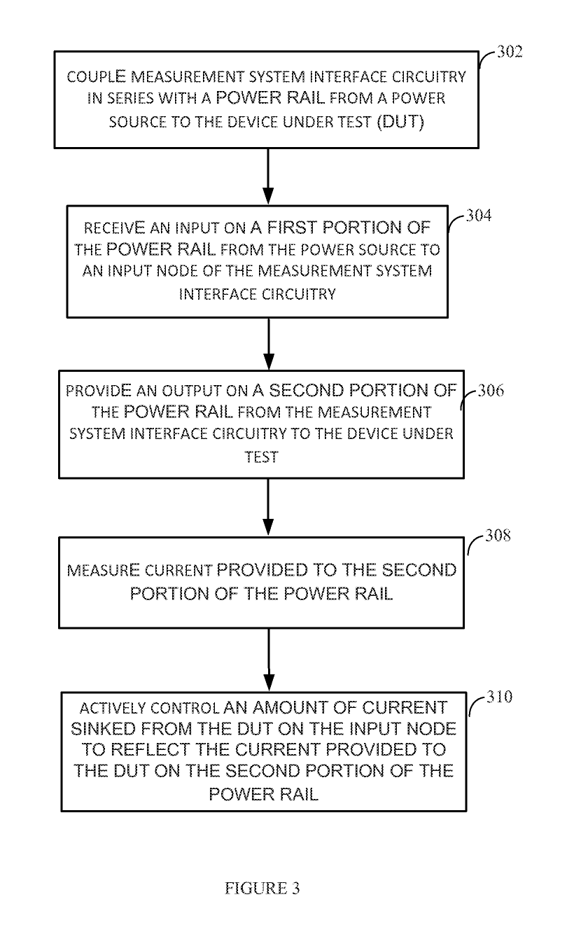

FIG. 3 is a process flow diagram illustrating a method of power measurement in a device under test according to aspects of the present disclosure. The method includes coupling measurement system interface circuitry in series with a power rail/load from a power source to the device under test in block 302. At block 304, an input is received on a first portion of the power rail/load from the power source to an input node of the measurement system interface circuitry. In block 306, an output voltage is provided on a second portion of the power rail/load from the measurement system interface circuitry to the device under test. The method further includes measuring current of to the second portion of the power rail/load in block 308, and actively controlling an amount of current sinked from the first portion of the power rail/load on the input node to reflect the current provided to the device under test on the second portion of the power rail/load in block 310.

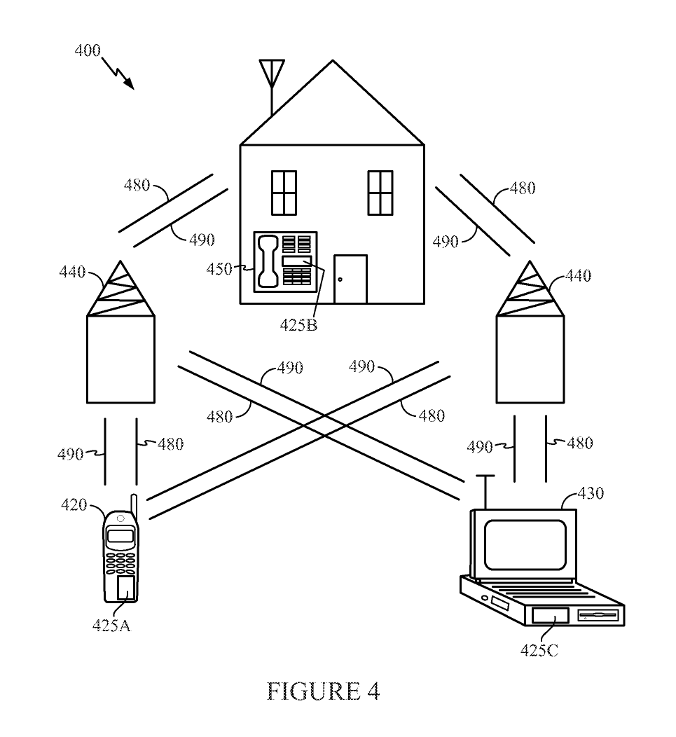

FIG. 4 is a block diagram showing an exemplary wireless communication system 400 in which an aspect of the disclosure may be advantageously employed. For purposes of illustration, FIG. 4 shows three remote units 420, 430, and 450 and two base stations 440. It will be recognized that wireless communication systems may have many more remote units and base stations. Remote units 420, 430, and 450 include IC devices 425A, 425C and 425B having power rails that can be tested, as described above. It will be recognized that other devices may also include the disclosed power rails, such as the base stations, switching devices, and network equipment. FIG. 4 shows forward link signals 480 from the base station 440 to the remote units 420, 430, and 450 and reverse link signals 490 from the remote units 420, 430, and 450 to base stations 440.

In FIG. 4, remote unit 420 is shown as a mobile telephone, remote unit 430 is shown as a portable computer, and remote unit 450 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 4 illustrates remote units according to the teachings of the disclosure, the disclosure is not limited to these exemplary illustrated units. Aspects of the disclosure may be suitably employed in many devices which include the disclosed power rails.

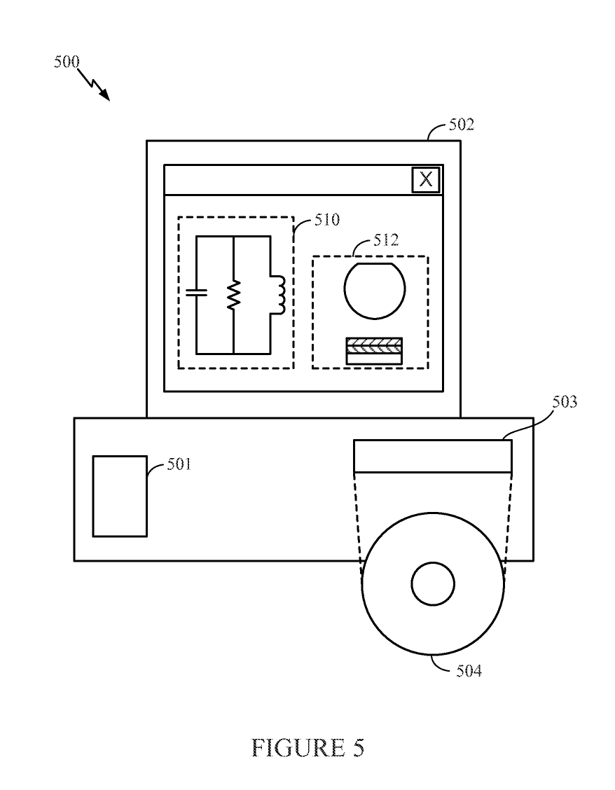

FIG. 5 is a block diagram illustrating a design workstation used for circuit, layout, and logic design of a semiconductor component, such as the power rails disclosed above. A design workstation 500 includes a hard disk 501 containing operating system software, support files, and design software such as Cadence or OrCAD. The design workstation 500 also includes a display 502 to facilitate design of a circuit 510 or a semiconductor component 512 including the disclosed power rails. A storage medium 504 is provided for tangibly storing the circuit design 510 or the semiconductor component 512. The circuit design 510 or the semiconductor component 512 may be stored on the storage medium 504 in a file format such as GDSII or GERBER. The storage medium 504 may be a CD-ROM, DVD, hard disk, flash memory, or other appropriate device. Furthermore, the design workstation 500 includes a drive apparatus 503 for accepting input from or writing output to the storage medium 504.

Data recorded on the storage medium 504 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 504 facilitates the design of the circuit design 510 or the semiconductor component 512, by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A method for measuring power in a device under test, comprising:
coupling measurement system interface circuitry in series with a power rail from a power source to the device under test;
receiving an input voltage on a first portion of the power rail from the power source to an input node of the measurement system interface circuitry;
providing an output on a second portion of the power rail from the measurement system interface circuitry to the device under test;
measuring at least one of current, power and voltage provided to the second portion of the power rail; and
actively controlling an amount of current sinked from the first portion of power rail on the input node to reflect current provided to the device under test on the second portion of the power rail.

2. The method of claim 1, further comprising:
comparing a first voltage of the input node to a second voltage of the output; and
controlling an output current based on a difference between the first voltage of the input node and the second voltage of the output.

3. The method of claim 1, further comprising:
controlling the voltage of the output based on a first voltage of the input node.

4. The method of claim 1, further comprising:
simultaneously sensing a voltage level of the output and a current level of the output.

5. The method of claim 4, further comprising:
outputting a voltage measurement signal representing the voltage level; and
simultaneously outputting a current measurement signal representing the current level.

6. The method of claim 1, further comprising:
selecting the power rail from a plurality of power rails in the device under test.

7. The method of claim 1, further comprising integrating the device under test into at least one of a mobile phone, a set top box, a music player, a video player, an entertainment unit, a navigation device, a computer, a hand-held personal communication systems (PCS) unit, a portable data unit, and a fixed location data unit.

8. An apparatus for measuring power in a device under test, comprising:
means for coupling measurement system interface circuitry in series with a power rail from a power source to the device under test;
means for receiving an input on a first portion of the power rail from the power source to an input node of the measurement system interface circuitry;
means for providing an output on a second portion of the power rail from the measurement system interface circuitry to the device under test;
means for measuring at least one of a current, power and voltage provided to the second portion of the power rail; and
means for actively controlling an amount of current sinked from the first portion of the power rail on the input node to reflect current provided to the second portion of the power rail.

9. The apparatus of claim 8, further comprising:
means for comparing a first voltage of the input to a second voltage of the output; and
means for controlling output current based on a difference between the first voltage of the input and the second voltage of the output.

10. The apparatus of claim 8, further comprising:
means for controlling a second voltage of the output based on a first voltage of the input.

11. The apparatus of claim 8, further comprising:
means for simultaneously sensing a voltage level of the output and a current level of the output.

12. The apparatus of claim 11, further comprising:
means for outputting a voltage measurement signal representing the voltage level; and
means for simultaneously outputting a current measurement signal representing the current level.

13. The apparatus of claim 8, further comprising:
means for selecting the power rail from a plurality of power rails in the device under test.

14. The apparatus of claim 8, in which the device under test is integrated into at least one of a mobile phone, a set top box, a music player, a video player, an entertainment unit, a navigation device, a computer, a hand-held personal communication systems (PCS) unit, a portable data unit, and a fixed location data unit.

15. An apparatus for measuring power in a device under test, comprising:
multiplexor circuitry coupled to a plurality of power rails of the device under test, the multiplexor circuitry configured to selectively couple a measurement channel in series with a selected one of the plurality of power rails;
an input node of the measurement channel coupled to a first source side of the selected one of the plurality of power rails;
an output node of the measurement channel coupled to a first load side of the selected one of the plurality of power rails; and
remote sense circuitry coupled between the input node and the output node, the remote sense circuitry configured to actively adjust a first current through the input node to mirror a second current through the output node.

16. The apparatus of claim 15, further comprising:
a shunt resistor configured for measuring the second current to the output node;
a current measurement amplifier coupled across the shunt resistor and configured to generate a current measurement signal;
a voltage measurement amplifier coupled to the output node and configured to generate a voltage measurement signal; and
an active load coupled to the input node and configured to control the first current through the shunt resistor in response to a voltage difference between the input node and the output node.

17. The apparatus of claim 15, in which the multiplexor circuitry is configured to short a second source side of each unselected one of the plurality of power rails to a second load side of a corresponding unselected power rail.

18. The apparatus of claim 15, in which the device under test is integrated into at least one of a mobile phone, a set top box, a music player, a video player, an entertainment unit, a navigation device, a computer, a hand-held personal communication systems (PCS) unit, a portable data unit, and a fixed location data unit.
